(19) United States
(12) Patent Application Publication
(10) Pub. No.: US 2005/0265483 A1
(43) Pub. Date: Dec. 1, 2005

(54) Digital noise coupling reduction and variable intermediate frequency generation in mixed signal circuits

(75) Inventor: Ozan E. Erdogan, Campbell, CA (US)

Correspondence Address: VAN PELT, YI & JAMES LLP, 10050 N. FOOTHILL BLVD #200, CUPERTINO, CA, 95014, US

(73) Assignee: Berkana Wireless, Inc.

(21) Appl. No.: 10/854,027

(22) Filed: May 25, 2004

(51) Int. Cl. H03D 1/04

(52) U.S. Cl. 375/316; 375/216

(57) ABSTRACT

A communications system comprises a local oscillator configured to generate a local oscillator output and a signal processing component coupled to the local oscillator. The signal processing component is configured to receive a clock signal and the clock signal is derived from the local oscillator output. A method of demodulating an input signal comprises deriving a conversion signal from a local oscillator output, deriving a clock signal from the local oscillator output, mixing the input signal with the conversion signal to generate an intermediate frequency signal, and processing the intermediate frequency signal using a signal processing component driven by the clock signal. A method of modulating an input signal comprise deriving a conversion signal from a local oscillator output, deriving a clock signal from the local oscillator output, processing the input signal using a signal processing component driven by the clock signal to generate an intermediate frequency signal and mixing the intermediate frequency signal with the conversion signal to generate a modulated signal.

### FIELD OF THE INVENTION

The present invention relates generally to communication systems. More specifically, a communications system for transmitting or receiving signals is disclosed.

### BACKGROUND OF THE INVENTION

As integrated circuit (IC) technology advances, it has become feasible to implement many functions that were traditionally implemented using analog circuits in the digital domain. It is advantageous to implement more functions using digital circuits since it is generally easier to simplify and scale digital circuits than analog circuits. Some circuits such as transceivers used in communication systems often have both analog and digital modules. These types of digital and analog circuits are sometimes referred to as mixed mode or mixed signal circuits. Mixed mode transceivers typically include a reference frequency source such as a temperature compensated crystal oscillator, used to derive both the analog signal used for modulating/demodulating the input signal and to derive the system clock used for driving the digital circuit.

Although implementing some of the functions in the digital domain simplifies the design, digital noise coupling may lead to performance degradation. For example, the harmonics of the digital clock frequency may appear in the desired signal band and cause interference. It would be useful if the effects of digital noise coupling can be reduced. Existing mixed signal circuit design has additional limitations. For example, in receiver circuits that employ a first stage analog IF demodulation and a second stage digital baseband demodulation, a digital local oscillator (LO) signal is generated at the IF frequency to demodulate the signal to baseband. In existing mixed mode transceivers, the choices of intermediate frequencies are often constrained due to limitations in the digital LO signals that may be conveniently generated. In these transceiver circuits, the IF signal is typically only adjustable among frequencies that correspond to available digital LO frequencies. The limited selection of intermediate frequencies may be undesirable. It may be useful sometimes to select among many available intermediate frequencies to improve image rejection or avoid interference from a digital clock driving digital circuitry on the chip or other source, or to otherwise avoid feed through of noise. It would be desirable to have a way of generating a variable intermediate frequency with small frequency increments.

### BRIEF DESCRIPTION OF THE DRAWINGS

Various embodiments of the invention are disclosed in the following detailed description and the accompanying drawings.

FIG. 1 is a block diagram illustrating a mixed mode receiver circuit.

FIG. 2A is a block diagram illustrating a receiver embodiment.

FIG. 2B is a block diagram illustrating a transmitter embodiment.

FIG. 3 is a block diagram illustrating another receiver example according to some embodiments.

### DETAILED DESCRIPTION

The invention can be implemented in numerous ways, including as a process, an apparatus, a system, a composition of matter, a computer readable medium such as a computer readable storage medium or a computer network wherein program instructions are sent over optical or electronic communication links. In this specification, these implementations, or any other form that the invention may take, may be referred to as techniques. In general, the order of the steps of disclosed processes may be altered within the scope of the invention.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

A communications system is disclosed. In some embodiments, a local oscillator is configured to generate an output that is used to derive a clock signal of a signal processing component. The local oscillator output may also be used to derive a conversion signal used for modulation or demodulation. In some embodiments, the clock signal and the conversion signals change in step. In some embodiments, the local oscillator uses a fractional N phase locked loop to provide an IF signal that can be fine tuned.

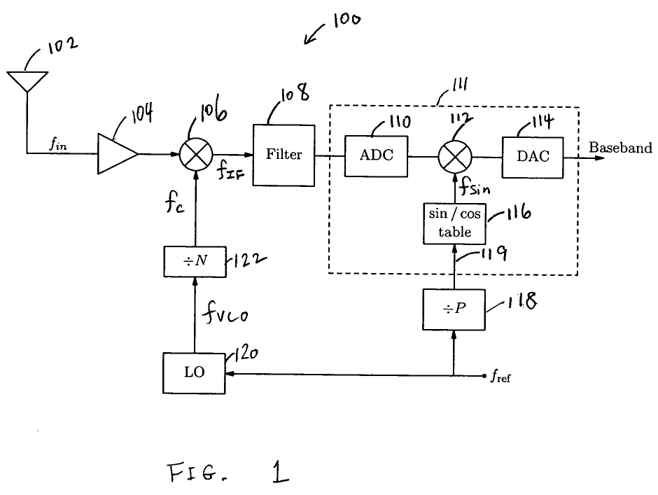

FIG. 1 is a block diagram illustrating a mixed mode receiver circuit. In this example, wireless receiver 100 includes an antenna 102 for receiving the transmitted signal and sending the signal to be amplified by a low noise amplifier (LNA) 104. The amplified signal from low noise amplifier 104 is down converted by analog mixer 106 by mixing with a conversion signal f_{C}. To supply f_{C}, the output of local oscillator 120 f_{VCO} is divided by an integer N via divider 122. Local oscillator 120 includes a phase locked loop (PLL) capable of generating signals at different frequencies. The input reference signal of local oscillator 120, f_{ref}, is generated by a TCXO or any other appropriate source.

The down converted IF signal is sent to a filter 108 and the filtered output is sent to digital module 111. The filtered output is converted to a digital signal by ADC 110. A digital mixer 112 combines the output of ADC 110 and a digital LO signal generated as a sine wave fₛᵢₙ to produce a down converted signal, which is then converted to a baseband (zero-IF) analog signal by digital to analog converter (DAC) 114. The digital sine wave is generated by a sin/cos coefficient table 116 that is clocked by a digital clock signal 119. The sin/cos coefficient table shown in this example is stored in read only memory (ROM). Since the cost of implementing the ROM table is proportional to the number of entries in the table, it is desirable to keep the table small. To generate digital clock signal 119, reference frequency f_{ref} is divided by an integer P via divider 118.

The frequency of the digital sine wave can be expressed as the following:

$${f}_{sin} = \frac{{f}_{ref}}{LP} , \qquad ( 1 )$$

where fₛᵢₙ is the frequency of the digital sine wave, f_{ref} is the frequency of the system clock, L is the number of digital samples per period of the digital sine wave, and P is the clock division ratio for the digital module. For example, assuming that f_{ref} is the same as the standard reference clock frequency of global system for mobile communications (GSM), which is 13 MHz; also assuming that there are 32 digital samples per period and P is set to 4, then

$${f}_{sin} = \frac{13 MHz}{4 \times 32} = 101.5625 kHz . \qquad ( 2 )$$

To obtain a baseband signal centered at DC, the IF frequency of the analog component (f_{IF}) should be equal to the frequency of the digital module (fₛᵢₙ). To vary the IF frequency and still provide zero IF output, P or L or both will change. Since it is desirable to keep the number of entries in the coefficient table small, changing L is impractical as the change will require additional entries in the coefficient table for each possible IF frequency. The value of L is fixed so that only one set of entries is required. Since the value of P is relatively small, any change in P will result in significant changes in fₛᵢₙ and f_{IF}. For example, in equation 2 shown above, changing P from 4 to 3 leads to a 30% change in f_{IF}. Since the selection of frequencies for f_{IF} is limited, it may not be possible to vary f_{IF} in a manner desired to improve image rejection or avoid noise feed through.

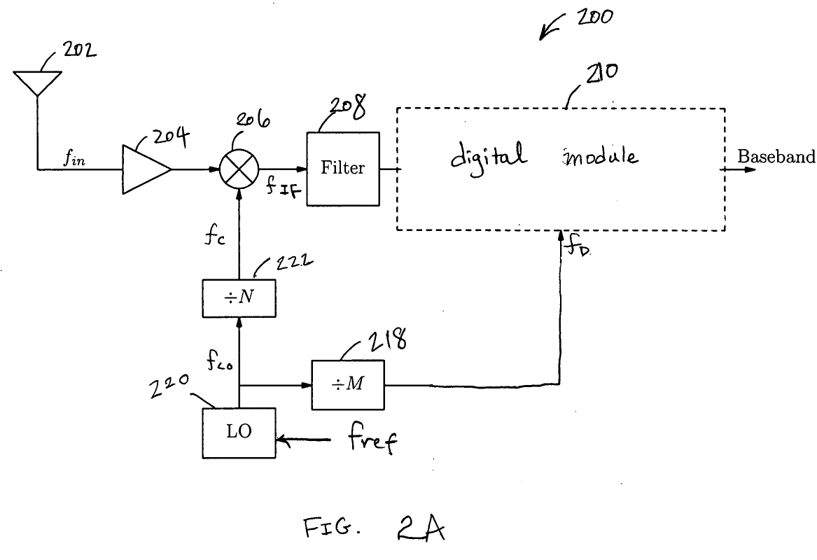

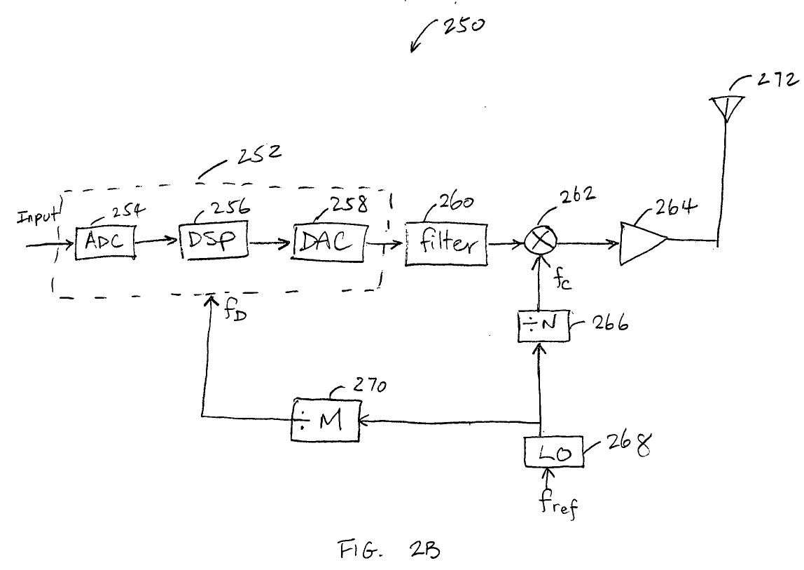

FIG. 2A is a block diagram illustrating a receiver embodiment that allows a variable intermediate frequency signal to be generated. In this example, receiver 200 derives both the analog signal for down conversion and the digital clock for the digital module from the local oscillator output. Receiver 200 includes an antenna 202 that receives the transmitted signal. The output of antenna 202 is amplified by an LNA 204, and then down converted to an intermediate frequency signal f_{IF} by mixing with an analog conversion signal f_{C} via mixer 206. The IF signal is filtered by filter 208, and the filtered signal is sent to a signal processing component 210 to be further processed and down converted to baseband. The signal processing component may include a digital module. The reference frequency f_{ref} is sent to local oscillator 220, whose output is divided by N via divider 222 to produce analog conversion signal f_{C} and divided by M via 218 to produce digital clock f_{D}. As will be shown in more details below, deriving both the analog IF signal and the digital clock from the local oscillator output increases the number of possible choices for f_{C} and helps reduce digital noise coupling.

The technique of deriving a digital system clock from the local oscillator is also applicable to transmitters. FIG. 2B is a block diagram illustrating a transmitter embodiment in which the digital clock is derived from the local oscillator output. In this example, transmitter 250 includes a signal processing component 252, which processes an input for transmission. The analog input is sent to ADC 254 to be converted to digital. DSP 256 processes the digital signal and performs functions such as digital modulation, filtering, etc. The output of DSP 256 is sent to DAC 258 to be converted back to analog and then filtered by a filter 260. The output of filter 260 is an intermediate frequency signal. Mixer 262 modulates the IF signal with a conversion signal f_{C} to generate a modulated signal, which is sent to a power amplifier 264. The output of power amplifier 264 is transmitted via antenna 272. Reference frequency f_{ref} is sent to local oscillator 268, which is configured to provide an output signal that is divided by N via divider 270 to supply the digital system clock f_{D}. The same output signal of the oscillator is divided by M via divider 266 to supply the conversion signal f_{C}.

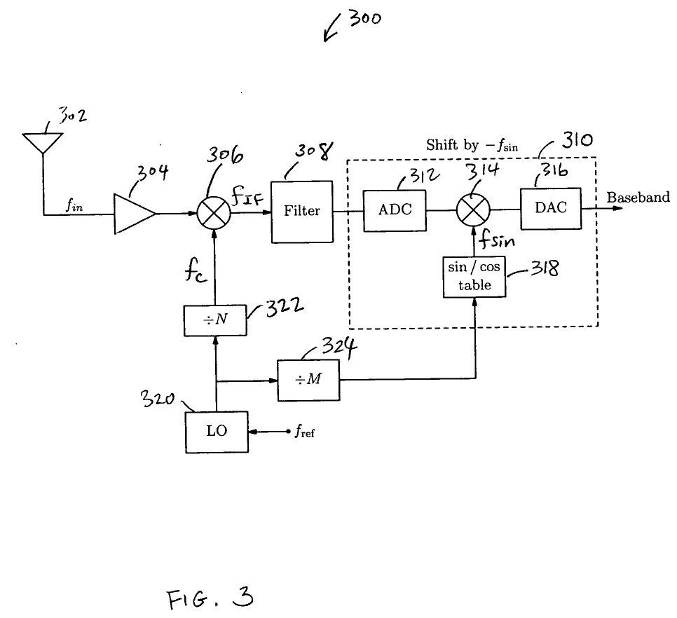

FIG. 3 is a block diagram illustrating another receiver example according to some embodiments. In this example, the transmitted signal is received by antenna 302 of receiver 300 and then sent to LNA 304. Analog mixer 306 down converts the amplified signal from LNA 304 by mixing it with a conversion signal f_{C}, which is generated by dividing the output of local oscillator 320 by N via divider 322. In some embodiments, the local oscillator includes a fractional N phase locked loop (PLL) that is capable of synthesizing a range of output signals at relatively small frequency increments. Thus, it is possible to fine tune the frequency of f_{C} and vary the frequency of f_{IF} with fine granularity to improve the receiver's image rejection ratio and noise characteristics, as well as to achieve better frequency planning.

The down converted IF signal is sent to a filter 308, which sends its output to down converter 310. In this example, down converter 310 performs down conversion in the digital domain. The filtered output is converted to a digital signal by ADC 312. A digital mixer 314 down converts the output of ADC 312 to baseband by mixing it with a digital sine wave fₛᵢₙ. The baseband digital signal is then converted to analog by digital to analog converter (DAC) 316. To generate fₛᵢₙ, the output of local oscillator 320 is divided by M via divider 324. A look-up table 318 generates samples of a sine wave using this clock.

In this example, both fₛᵢₙ and f_{C} are derived from the output of local oscillator 320. The relationship between various signals may be expressed as the following:
f_{IF}=fᵢₙ−f_{C} (3),
where fᵢₙ is the input signal frequency; and

$${f}_{sin} = \frac{{Nf}_{C}}{ML} , \qquad ( 4 )$$

where L is the number of digital samples per period of fₛᵢₙ.

Setting f_{IF}=fᵢₙ and solving for f_{C} results in

$${f}_{C} = \frac{{f}_{in}}{1 + \frac{N}{ML}} . \qquad ( 5 )$$

Substituting (5) into (3) results in

$${f}_{IF} = {f}_{in} \frac{\frac{N}{ML}}{1 + \frac{N}{ML}} . \qquad ( 6 )$$

The frequency of f_{IF} may be controlled by changing the value of divider M. In many communications applications, the frequency difference between f_{C} and fₛᵢₙ is large, thus M can be chosen to be a relatively large value such that a small change in M leads to a small change in f_{IF}. For example, assuming that fᵢₙ=935 MHz, N=2, L=32 and M=584, the resulting f_{IF} is equal to 100 kHz. Incrementing or decrementing M by 1 results in less than 0.2% change in the frequency of f_{IF}, allowing the frequency to be tuned on a fine scale. In some embodiments, fₛᵢₙ may be indirectly derived from the output of local oscillator 320. For example, the input to divider 324 may be f_{C} rather than the local oscillator output.

In some embodiments, the frequency of f_{IF} is tuned before the transceiver begins its operations. For example, the f_{IF} frequency of a transceiver used in a cellular phone may be calibrated at the factory based on test measurements. In some embodiments, the f_{IF} frequency is adjusted during the transceiver's operation. For example, when a cell phone is switched on, if improved image rejection is deemed necessary or if it is determined that there is excess noise feed through due to signal harmonics, the f_{IF} of a cell phone transmitter may be tuned to improve the image rejection ratio or noise characteristics or both.

In the examples shown, the frequencies of the conversion signal and the digital signal track each other. In other words, when the local oscillator output changes, both f_{C} and f_{D} change proportionally. This also prevents harmonics of digital clock from falling into the desired signal band of the input. The harmonics of digital noise are at integer multiples of digital clock frequency f_{D}. Since f_{C} and f_{D} track each other, there is a relatively stable and predictable relation between f_{C} and digital noise harmonics. Therefore, it is possible to choose an IF frequency, f_{IF}, that keeps harmonics of digital noise away from fᵢₙ, which can be expressed as f_{C}±f_{IF}. The following example shows how to choose a proper f_{IF} in the system shown in FIG. 2A, according to some embodiments. Two harmonics of f_{D} closest to f_{C} satisfy the following relation:
nf_{D}≦f_{C}<(n+1)f_{D} (7)
In other words, for some integer number n, the n-th harmonic is the closest harmonic of f_{D} below or at f_{C} and the (n+1)-th harmonic is above f_{C}. Dividing this equation by f_{D} gives:
n≦f_{C}/f_{D}<n+1 (8)
This equation can also be written as:
n=floor[f_{C}/f_{D}] (9)
From FIG. 2A:

$$\begin{matrix}{f}_{D} = \frac{{f}_{LO}}{M} & ( 10 ) \\ {f}_{C} = \frac{{f}_{LO}}{N} & ( 11 )\end{matrix}$$

f_{C}/f_{D}=M/N=n+r/N (0≦r<N) (12)
Where n is the integer part of the division of f_{C} by f_{D} as in Equation (9) and r/N is the fractional part. Applying (7), (9), and (12), the distance between the n-th harmonic and f_{C}, Δ_{L}, is:
Δ_{L}=f_{C}−nf_{D} (13)
Δ_{L}=M/Nf_{D}−nf_{D} (14)
Δ_{L}=(n+r/N)f_{D}−nf_{D} (15)
Δ_{L}=r/Nf_{D} (16)
Similarly, the distance between (n+1)-th harmonic and f_{C}, Δ_{H}, is:
Δ_{H}=(n+1)f_{D}−f_{C} (17)
Δ_{H}=(n+1)f_{D}−M/Nf_{D} (18)
Δ_{H}=(n+1)f_{D}−(n+r/N)f_{D} (19)
Δ_{H}=(1−r/N)f_{D} (20)
Since r is limited to values in the range 0-N−1, the possible values of Δ_{L} and Δ_{H} are 0, f_{D}/N, 2f_{D}/N, . . . , (N−1)f_{D}/N. This means that the closest two harmonics of f_{D} are located at f_{C}, f_{C}±f_{D}/N, fc±2f_{D}/N, etc. With a properly chosen IF frequency, the desired channel at fᵢₙ does not substantially coincide with the harmonic locations, thus interference from the digital noise is avoided. For example, fᵢₙ may be kept between possible harmonic locations, f_{C} and f_{C}+f_{D}/N:
f_{C}<fᵢₙ=f_{C}+f_{IF}<f_{C}+f_{D}/N (21)
0<f_{IF}<f_{D}/N (22)
The digital clock frequency f_{D} varies as f_{LO}, and M changes. However, this does not necessarily affect system performance because f_{IF} can be chosen to keep the desired channel away from possible harmonics even with varying f_{D}. For example, if f_{D} varies from 10 MHz to 20 Mhz (100% variation), and N is 2, choosing f_{IF} to be less than 5 MHz would guarantee that the harmonics of f_{D} do not substantially coincide with the desired channel to cause interference.

A technique for generating a variable intermediate frequency signal in a communications system and eliminating noise coupling been disclosed. Although the examples shown above discuss in detail the operations of transceivers used in GSM systems, the technique is also applicable for other standards and frequency ranges.

Although the foregoing embodiments have been described in some detail for purposes of clarity of understanding, the invention is not limited to the details provided. There are many alternative ways of implementing the invention. The disclosed embodiments are illustrative and not restrictive.

1. A communications system comprising:
a local oscillator configured to generate a local oscillator output; and
a signal processing component coupled to the local oscillator;
wherein the signal processing component is configured to receive a clock signal; and the clock signal is derived from the local oscillator output.

2. A communications system as recited in claim 1, wherein the clock signal and the local oscillator output are configured to track each other.

3. A communications system as recited in claim 1, wherein the clock signal and the local oscillator output are configured such that harmonics of the clock signal do not substantially coincide with an input of the system.

4. A communications system as recited in claim 1, wherein the local oscillator output is used to derive a conversion signal.

5. A communications system as recited in claim 1, wherein the clock signal is derived from the local oscillator output by dividing the local oscillator output.

6. A communications system as recited in claim 1, wherein the local oscillator output is used to derive a conversion signal used to demodulate an input to the system.

7. A communications system as recited in claim 1, wherein the local oscillator output is used to derive a conversion signal used to modulation a system input signal.

8. A communications system as recited in claim 1, wherein the local oscillator includes a fractional N frequency synthesizer.

9. A communications system as recited in claim 1, wherein the signal processing component includes a digital module.

10. A communications system as recited in claim 1, wherein the clock signal is used to generate a digital sine wave.

11. A communications system as recited in claim 1, wherein:
the local oscillator output is used to derive a conversion signal used to demodulate a system input signal to obtain an intermediate frequency (IF) signal;
the clock signal is used to generate a digital sine wave; and
the digital sine wave is used to demodulate the IF signal to baseband.

12. A communications system as recited in claim 1, wherein the local oscillator and signal processing component are implemented on the same integrated circuit chip.

13. A communications system as recited in claim 1, wherein the local oscillator is tuned before the system begins operation.

14. A communications system as recited in claim 1, wherein the local oscillator is tuned during the system's operation.

15. A method of demodulating an input signal, comprising:
deriving a conversion signal from a local oscillator output;
deriving a clock signal from the local oscillator output;
mixing the input signal with the conversion signal to generate an intermediate frequency signal; and
processing the intermediate frequency signal using a signal processing component driven by the clock signal.

16. A method of demodulating an input signal as recited in claim 15, further comprising tracking frequencies of the clock signal and the conversion signal.

17. A method of demodulating an input signal as recited in claim 15, further comprising tracking frequencies of the clock signal and the conversion signal such that harmonics of the clock signal does not substantially coincide with the input signal.

18. A method of demodulating an input signal as recited in claim 15, wherein processing the intermediate frequency signal includes mixing the intermediate frequency signal with a digital sine signal derived from the clock signal.

19. A method of demodulating an input signal as recited in claim 15, wherein the local oscillator includes a fractional N frequency synthesizer.

20. A method of demodulating an input signal as recited in claim 15, wherein the clock signal is used to generate a digital sine wave.

21. A method of demodulating an input signal as recited in claim 15, wherein:
the local oscillator output is used to derive a conversion signal used to demodulate a system input signal to obtain an intermediate frequency (IF) signal;
the clock signal is used to generate a digital sine wave; and
the digital sine wave is used to demodulate the IF signal to baseband.

22. A method of demodulating an input signal as recited in claim 15, wherein the local oscillator is tuned before the system begins operation.

23. A method of demodulating an input signal as recited in claim 15, wherein the local oscillator is tuned during the system's operation.

24. A method of modulating an input signal, comprising:
deriving a conversion signal from a local oscillator output;
deriving a clock signal from the local oscillator output;
processing the input signal using a signal processing component driven by the clock signal to generate an intermediate frequency signal; and
mixing the intermediate frequency signal with the conversion signal to generate a modulated signal.

25. A method of modulating an input signal as recited in claim 24, further comprising tracking frequencies of the clock signal and the conversion signal.

26. A method of modulating an input signal as recited in claim 24, further comprising tracking frequencies of the clock signal and the conversion signal such that harmonics of the clock signal do not substantially coincide with the input signal.

27. A method of modulating an input signal as recited in claim 24, wherein processing the input signal includes mixing the input signal with a digital sine signal derived from the clock signal.

28. A method of modulating an input signal as recited in claim 24, wherein the local oscillator includes a fractional N frequency synthesizer.

29. A method of modulating an input signal as recited in claim 24, wherein the clock signal is used to generate a digital sine wave.

30. A method of modulating an input signal as recited in claim 24, wherein the clock signal is used to derive a digital sine signal used to modulate the input signal to obtain an intermediate frequency (IF) signal.

31. A method of modulating an input signal as recited in claim 24, wherein the local oscillator is tuned before the system begins operation.

32. A method of modulating an input signal as recited in claim 24, wherein the local oscillator is tuned during the system's operation.
